(19) United States
(12) Patent Application Publication
(10) Pub. No.: US 2025/0392324 A1
(43) Pub. Date: Dec. 25, 2025

(54) ANALOG-TO-DIGITAL CONVERSION DEVICE AND OPTICAL SENSOR

(71) Applicant: Sharp Semiconductor Innovation Corporation, Tenri City (JP)

(72) Inventors: Kohji HAMAGUCHI, Tenri City (JP); Takahiro INOUE, Tenri City (JP); AHMAD SHAHIR BIN AHMAD NOR, Tenri City (JP)

(21) Appl. No.: 19/242,139

(22) Filed: Jun. 18, 2025

(30) Foreign Application Priority Data
Jun. 21, 2024 (JP) 2024-100143

(51) Int. Cl. H03M 3/00

(52) U.S. Cl. CPC H03M 3/458

(57) ABSTRACT

An analog-to-digital conversion device includes: a ΔΣ analog-to-digital converter configured to convert an analog signal into a digital signal having a pulse width corresponding to a magnitude of the analog signal; first to nth delay circuits, the first delay circuit being configured to delay the digital signal to generate a first delay signal, the ith delay circuit being configured to delay an i−1th delay signal to generate an ith delay signal, where i is an integer equal to or greater than two and equal to or smaller than n, and where n is an integer equal to or greater than two; and a signal processing circuit configured to obtain a signal value corresponding to the magnitude, from the digital signal and the first delay signal to an nth delay signal.

### CROSS-REFERENCE TO RELATED APPLICATION

The present application claims priority from Japanese Application JP2024-100143, the content of which is hereby incorporated by reference into this application.

### BACKGROUND OF THE INVENTION

### 1. Field of the Invention

The present disclosure relates to an analog-to-digital conversion device and an optical sensor.

### 2. Description of the Related Art

Japanese Unexamined Patent Application Publication No. 2023-75782 discloses an analog-digital converter. In the analog-to-digital converter, a charge circuit is charged by an input current to increase an output signal. A comparator circuit brings a comparison signal into a high voltage upon the output signal exceeding a reference voltage. A flip-flop samples the comparison signal, and brings a charge signal into a high voltage upon the comparison signal being brought into the high voltage. A discharge circuit discharges the charge circuit to lower the output signal upon the charge signal being brought into the high voltage. A counter counts the number of discharges of the discharge circuit. The counter thus outputs a digital value corresponding to the input current (paragraphs 0003 to 0010).

### SUMMARY OF THE INVENTION

In an optical sensor, a current corresponding to the intensity of light received by a photodiode flows through the photodiode in many cases, and a ΔΣ analog-to-digital converter, such as the analog-to-digital converter disclosed in Japanese Unexamined Patent Application Publication No. 2023-75782, generates a signal value corresponding to the flowing current.

To enhance the sensitivity of the optical sensor, it is effective to enhance the sensitivity of the photodiode by increasing the size of the photodiode. However, since the size of the photodiode affects the size of the optical sensor considerably, the optical sensor's size becomes remarkably large when the photodiode's size is increased. Accordingly, enhancing the sensitivity of the ΔΣ analog-to-digital converter is expected without increasing the photodiode's size.

The ΔΣ analog-to-digital converter performs oversampling. The performed oversampling contributes to enhancing the sensitivity of the ΔΣ analog-to-digital converter. Unfortunately, when the optical sensor is disposed on the backside of an organic light-emitting diode (OLED) display panel and is used as an illumination sensor, the fact that a measurement time must be shortened negates the oversampling's effect.

To enhance the sensitivity of the ΔΣ analog-to-digital converter, it is effective to increase the frequency of the sampling, which is performed by the ΔΣ analog-to-digital converter. Unfortunately, if the sampling's frequency is increased, a large-scale circuit, such as a phase-locked loop (PLL) circuit, is needed, thus increasing the current consumption of the ΔΣ analog-to-digital converter.

To enhance the sensitivity of the ΔΣ analog-to-digital converter, it is also effective to calculate the average of a plurality of signal values to obtain an ultimate signal value. Unfortunately, if the average of the plurality of signal values is calculated to obtain the ultimate signal value, the measurement time elongates, and the obtained ultimate signal value is limited to multiples of the number of additions, thereby increasing quantization error in some cases.

One aspect of the present disclosure has been made in view of these problems. One aspect of the present disclosure aims to provide a ΔΣ analog-to-digital converter and an optical sensor that, for instance, can prevent sampling frequency from increase, prevent measurement time from elongation, and have high sensitivity.

An analog-to-digital conversion device according to a first aspect of the present disclosure includes the following: a ΔΣ analog-to-digital converter configured to convert an analog signal into a digital signal having a pulse width corresponding to the magnitude of the analog signal; first to nth delay circuits, the first delay circuit being configured to delay the digital signal to generate a first delay signal, the ith delay circuit being configured to delay an i−1th delay signal to generate an ith delay signal, where i is an integer equal to or greater than two and equal to or smaller than n, and where n is an integer equal to or greater than two; and a signal processing circuit configured to obtain a signal value corresponding to the magnitude, from the digital signal and the first delay signal to an nth delay signal.

An optical sensor according to a second aspect of the present disclosure includes the analog-to-digital conversion device according to the first aspect of the present disclosure, and a light detecting element configured to convert light into the analog signal.

### BRIEF DESCRIPTION OF THE DRAWINGS

FIG. 1 is a circuit diagram of an optical sensor according to a first embodiment;

FIG. 2 is a diagram showing an example relationship between the magnitude of an analog signal input to a ΔΣ analog-to-digital converter provided in the optical sensor according the first embodiment and the waveform of a digital signal output from the ΔΣ analog-to-digital converter;

FIG. 3 is a timing chart showing example waveforms of a clock signal and a digital signal input to a sampling circuit provided in an optical sensor according to a reference example; and

FIG. 4 is a timing chart showing example waveforms of a clock signal, the digital signal, and first to third delay signals input to a sampling circuit provided in the optical sensor according to the first embodiment.

### DETAILED DESCRIPTION OF THE INVENTION

The embodiment of the present disclosure will be described with reference to the drawings. It is noted that identical or equivalent constituents will be denoted by the same signs throughout the drawings, and the descriptions of redundancies will be omitted.

### 1 First Embodiment

### 1.1 Optical Sensor

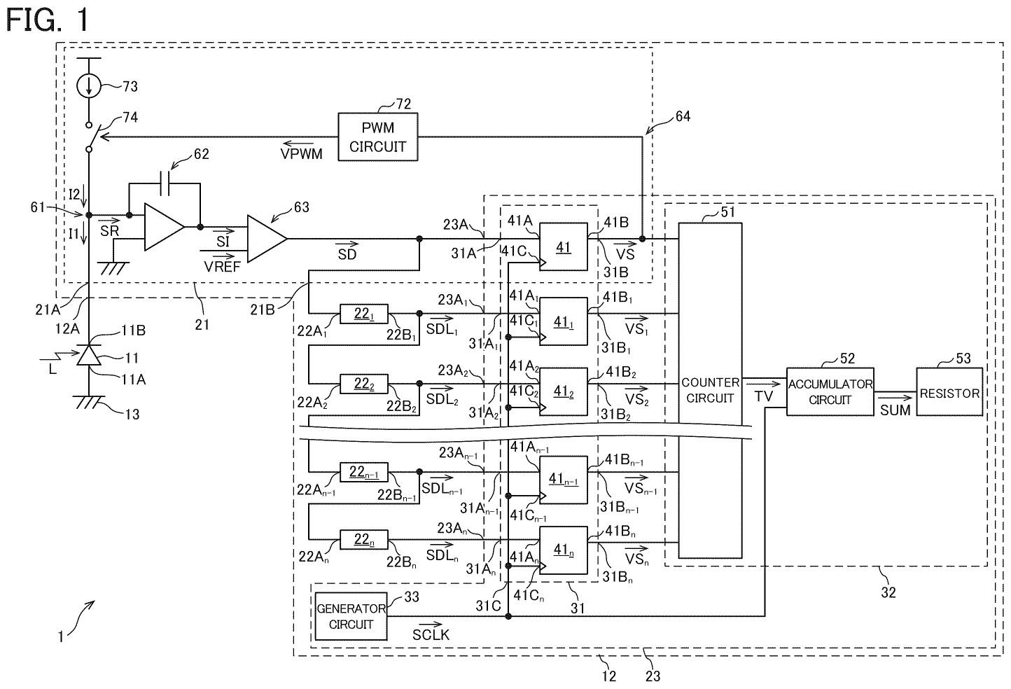

FIG. 1 is a circuit diagram of an optical sensor according to a first embodiment.

The optical sensor, 1, according to the first embodiment illustrated in FIG. 1 receives light L and generates a signal value SUM corresponding to the intensity of the received light L.

As illustrated in FIG. 1, the optical sensor 1 includes a photodiode 11, an analog-to-digital conversion device 12, and a ground 13. The photodiode 11 includes an anode 11A and a cathode 11B. The analog-to-digital conversion device 12 includes an input terminal 12A.

The cathode 11B of the photodiode 11 is electrically connected to the input terminal 12A of the analog-to-digital conversion device 12. The anode 11A of the photodiode 11 is electrically connected to the ground 13.

The photodiode 11 receives the light L. A current I1 corresponding to the intensity of the light L received by the photodiode 11 flows through the photodiode 11. The current I1 flows from the cathode 11B of the photodiode 11 toward the anode 11A of the photodiode 11. The current I1 accordingly flows out of the input terminal 12A of the analog-to-digital conversion device 12. The current I1 flowed out of the input terminal 12A of the analog-to-digital conversion device 12 flows into the cathode 11B of the photodiode 11. The current I1 flowed into the cathode 11B of the photodiode 11 flows out of the anode 11A of the photodiode 11. The current flowed out of the anode 11A of the photodiode 11 flows into the ground 13.

Accordingly, the photodiode 11 converts the received light L into an analog signal composed of the current I1. The analog signal is input to the input terminal 12A of the analog-to-digital conversion device 12. The analog-to-digital conversion device 12 generates the signal value SUM corresponding to the magnitude of the input analog signal.

The photodiode 11 is an example of a light detecting element. The photodiode 11 may be replaced with a light detecting element other than the photodiode 11.

### 1.2 Analog-to-Digital Conversion Device

As illustrated in FIG. 1, the analog-to-digital conversion device 12 includes a ΔΣ analog-to-digital converter 21, first to nth delay circuits 22₁, 22₂, . . . , 22ₙ₋₁, and 22ₙ, and a signal processing circuit 23. The ΔΣ analog-to-digital converter 21 includes an input terminal 21A and an output terminal 21B. The first to nth delay circuits 22₁, 22₂, . . . , 22ₙ₋₁, and 22ₙ respectively include input terminals 22A₁, 22A₂, . . . , 22Aₙ₋₁, and 22Aₙ, and respectively include output terminals 22B₁, 22B₂, . . . , 22Bₙ₋₁, and 22Bₙ. The signal processing circuit 23 includes an input terminal 23A and input terminals 23A₁, 23A₂, . . . , 23Aₙ₋₁, and 23Aₙ. The lowercase n is an integer equal to or greater than two. The first to nth delay circuits 22₁, 22₂, . . . , 22ₙ₋₁, and 22ₙ are also called delay lines or other names.

The input terminal 21A of the ΔΣ analog-to-digital converter 21 is electrically connected to the input terminal 12A of the analog-to-digital conversion device 12. The input terminal 22A₁ of the first delay circuit 22₁ is electrically connected to the output terminal 21B of the ΔΣ analog-to-digital converter 21. The input terminal 22Aᵢ of the ith delay circuit 22; is electrically connected to the output terminal 22Bᵢ₋₁ of the i−1th delay circuit 22ᵢ₋₁. The lowercase i is an integer equal to or greater than two and equal to or smaller than n. That is, the input terminals 22A₂, . . . , 22Aₙ₋₁, and 22Aₙ of the second to nth delay circuits 22₂, . . . , 22ₙ₋₁, and 22ₙ are respectively electrically connected to the output terminals 22B₁, 22B₂, . . . , and 22Bₙ₋₁ of the first to n−1th delay circuits 22₁, 22₂, . . . , and 22ₙ₋₁. The first to nth delay circuits 22₁, 22₂, . . . , 22ₙ₋₁, and 22ₙ are thus electrically connected in series. The input terminal 23A of the signal processing circuit 23 is electrically connected to the output terminal 21B of the ΔΣ analog-to-digital converter 21. The input terminals 23A₁, 23A₂, . . . , 23Aₙ₋₁, and 23Aₙ of the signal processing circuit 23 are respectively electrically connected to the output terminals 22B₁, 22B₂, . . . , 22Bₙ₋₁, and 22Bₙ of the first to nth delay circuits 22₁, 22₂, . . . , 22ₙ₋₁, and 22ₙ.

The analog signal input to the input terminal 12A of the analog-to-digital conversion device 12 is input to the input terminal 21A of the ΔΣ analog-to-digital converter 21. The ΔΣ analog-to-digital converter 21 converts the input analog signal into a digital signal SD. The digital signal SD obtained through the conversion is output from the output terminal 21B of the ΔΣ analog-to-digital converter 21.

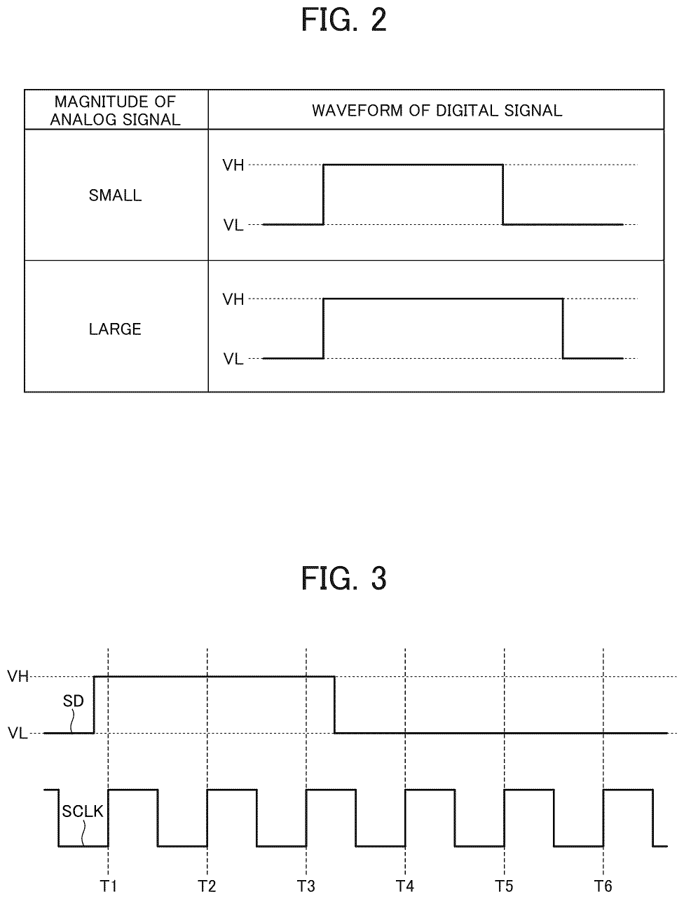

FIG. 2 is a diagram showing an example relationship between the magnitude of an analog signal input to the ΔΣ analog-to-digital converter provided in the optical sensor according the first embodiment and the waveform of a digital signal output from the ΔΣ analog-to-digital converter. The waveform is shown by a graph with time on the horizontal axis and with the digital signal's voltage on the vertical axis.

As illustrated in FIG. 2, the voltage of the digital signal SD, which is output from the ΔΣ analog-to-digital converter 21, varies with time to constitute a first voltage VH or a second voltage VL. The digital signal SD has a pulse width corresponding to the magnitude of the analog signal. The pulse width of the digital signal SD becomes higher along with increase in the magnitude of the analog signal. That is, the ratio of a time during which the voltage of the digital signal SD is the first voltage VH, to a measurement time increases along with increase in the magnitude of the analog signal.

The digital signal SD output from the output terminal 12B of the analog-to-digital conversion device 12 is input to the input terminal 22A1 of the first delay circuit 22₁ illustrated in FIG. 1. The first delay circuit 22₁ delays the input digital signal SD by a delay amount D to generate a first delay signal SDL₁. The generated first delay signal SDL₁ is output from the output terminal 22B₁ of the first delay circuit 22₁.

An i−1th delay signal SDLᵢ₋₁ output from the output terminal 22Bᵢ₋₁ of the i−1th delay circuit 22ᵢ₋₁ is input to the input terminal 22Aᵢ of the ith delay circuit 22ᵢ. The ith delay circuit 22ᵢ. delays the input i−1th delay signal SDLᵢ₋₁ by the delay amount D to generate an ith delay signal SDLᵢ. The generated ith delay signal SDLᵢ is output from the output terminal 22Bᵢ of the ith delay circuit 22ᵢ. The lowercase i is an integer equal to or greater than two and equal to or smaller than n. That is, the first to n−1th delay signals SDL₁, SDL₂, . . . , and SDLₙ₋₁ output from the output terminals 22B₁, 22B₂, . . . , and 22Bₙ₋₁ of the first to n−1th delay circuits 22₁, 22₂, . . . , and 22ₙ₋₁ are respectively input to the input terminals 22A₂, . . . , 22Aₙ₋₁, and 22Aₙ of the second to nth delay circuits 22₂, . . . , 22ₙ₋₁, and 22ₙ. The second to nth delay circuits 22₂, . . . , 22ₙ₋₁, and 22ₙ respectively delay the input first to n−1th delay signals SDL₁, SDL₂, . . . , and SDLₙ₋₁ by the delay amount D, to respectively generate the second to nth delay signals SDL₂, . . . , SDLₙ₋₁, and SDLₙ. The generated second to nth delay signals SDL₂, . . . , SDLₙ₋₁, and SDLₙ are respectively output from the output terminals 22B₂, . . . , 22Bₙ₋₁, and 22Bₙ of the second to nth delay circuits 22₂, . . . , 22ₙ₋₁, and 22ₙ.

The digital signal SD output from the output terminal 21B of the ΔΣ analog-to-digital converter 21 is input to the input terminal 23A of the signal processing circuit 23. The first to nth delay signals SDL₁, SDL₂, . . . , SDLₙ₋₁, and SDLₙ output from the output terminals 22B₁, 22B₂, . . . , 22Bₙ₋₁, and 22Bₙ of the first to nth delay circuits 22₁, 22₂, . . . , 22ₙ₋₁, and 22ₙ are respectively input to the input terminals 23A₁, 23A₂, . . . , 23Aₙ₋₁, and 23Aₙ of the signal processing circuit 23. The signal processing circuit 23 generates the signal value SUM corresponding to the magnitude of the analog signal, from the input digital signal SD and the input first to nth delay signals SDL₁, SDL₂, . . . , SDLₙ₋₁, and SDLₙ, and the signal processing circuit 23 stores the generated signal value SUM.

### 1.3 Signal Processing Circuit

As illustrated in FIG. 1, the signal processing circuit 23 includes a sampling circuit 31, an operation circuit 32, and a generator circuit 33.

The sampling circuit 31 includes an input terminal 31A, input terminals 31A₁, 31A₂, . . . , 31Aₙ₋₁, and 31Aₙ, an output terminal 31B, output terminals 31B₁, 31B₂, . . . , 31Bₙ₋₁, and 31Bₙ, and a clock terminal 31C.

The input terminal 31A of the sampling circuit 31 is electrically connected to the input terminal 23A of the signal processing circuit 23. The input terminals 31A₁, 31A₂, . . . , 31Aₙ₋₁, and 31Aₙ of the sampling circuit 31 are respectively electrically connected to the input terminals 23A₁, 23A₂, . . . , 23Aₙ₋₁, and 23Aₙ of the signal processing circuit 23. The operation circuit 32 is electrically connected to the output terminal 31B and output terminals 31B₁, 31B₂, . . . , 31Bₙ₋₁, and 31Bₙ of the sampling circuit 31.

The digital signal SD input to the input terminal 23A of the signal processing circuit 23 is input to the input terminal 31A of the sampling circuit 31. The first to nth delay signals SDL₁, SDL₂, . . . , SDLₙ₋₁, and SDLₙ input to the input terminals 23A₁, 23A₂, . . . , 23Aₙ₋₁, and 23Aₙ of the signal processing circuit 23 are respectively input to the input terminals 31A₁, 31A₂, . . . , 31Aₙ₋₁, and 31Aₙ of the sampling circuit 31. The sampling circuit 31 receives a clock signal SCLK from the terminal 31C. The sampling circuit 31 samples the voltage of the input digital signal SD to output a sampled voltage VS. The sampling circuit 31 samples the voltages of the input first to nth delay signals SDL₁, SDL₂, . . . , SDLₙ₋₁, and SDLₙ, to output first to nth sampled voltages VS₁, VS₂, . . . , VSₙ₋₁, and VSₙ. The sampled voltage VS is output from the output terminal 31B of the sampling circuit 31. The first to nth sampled voltages VS₁, VS₂, . . . , VSₙ₋₁, and VSₙ are respectively output from the output terminals 31B₁, 31B₂, . . . , 31Bₙ₋₁, and 31Bₙ of the sampling circuit 31. The sampling circuit 31 samples the voltage of the digital signal SD and the voltages of the first to nth delay signals SDL₁, SDL₂, . . . , SDLₙ₋₁, and SDLₙ simultaneously in synchronization at the edge timing of the input clock signal SCLK. The edge may be either a rising edge or a falling edge. The first to nth delay signals SDL₁, SDL₂, . . . , SDLₙ₋₁, and SDLₙ are delayed from the digital signal SD by delay amounts 1×D, 2×D, . . . , (n−1)×D, and n×D, respectively. Thus, the first to nth sampled voltages VS₁, VS₂, . . . , VSₙ₋₁, and VSₙ are equal to voltages output when the voltage of the digital signal SD undergoes sampling at the timings delayed from the timing of sampling the voltage of the digital signal SD by the delay amounts 1×D, 2×D, . . . , (n−1)×D, and n×D.

The sampled voltage VS and the first to nth sampled voltages VS₁, VS₂, . . . , VSₙ₋₁, and VSₙ are input to the operation circuit 32. The operation circuit 32 generates the signal value SUM from the sampled voltage VS and the first to nth sampled voltages VS₁, VS₂, . . . , VSₙ₋₁, and VSₙ, and stores the generated signal value SUM. At this time, the operation circuit 32 increases the count number by one when each of the sampled voltage VS and first to nth sampled voltages VS₁, VS₂, . . . , VSₙ₋₁, and VSₙ is the first voltage VH, and the operation circuit 32 maintains the count number when each voltage is the second voltage VL.

FIG. 3 is a timing chart showing example waveforms of a clock signal and a digital signal input to a sampling circuit provided in an optical sensor according to a reference example. In the timing chart of FIG. 3, the lateral axis indicates time, and the longitudinal axis indicates voltage.

As shown in FIG. 3, the optical sensor according to the reference example samples the voltage of the digital signal SD at the rising edge timings T1, T2, T3, T4, T5, and T6 of the clock signal SCLK within a measurement time. The voltage of the digital signal SD is the first voltage VH at the timings T1, T2, and T3, and is the second voltage VL at the timings T4, T5, and T6. Thus, the count number is increased by one at each of the timings T1, T2, and T3, and is maintained at each of the timings T4, T5, and T6. Accordingly, a count number of 3 is obtained after the end of the measurement time.

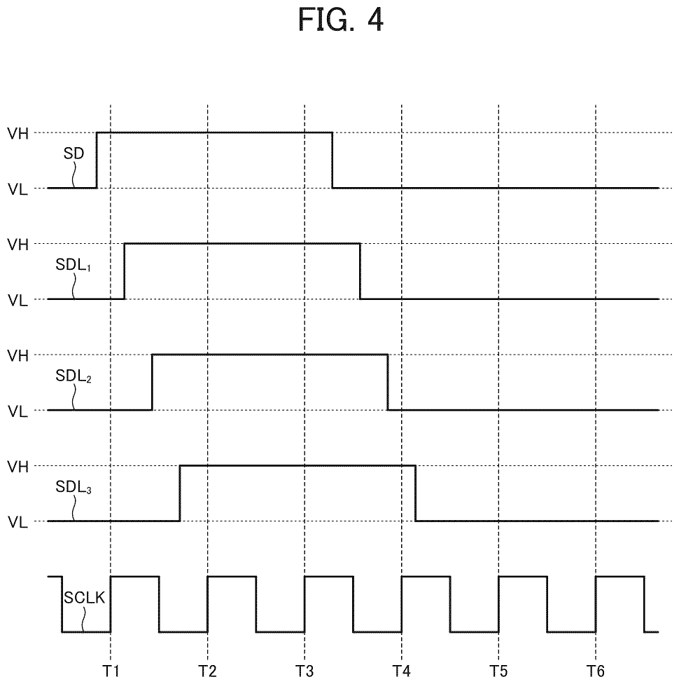

FIG. 4 is a timing chart showing example waveforms of the clock signal, digital signal, and first to third delay signals input to the sampling circuit provided in the optical sensor according to the first embodiment. In the timing chart of FIG. 4, the lateral axis indicates time, and the longitudinal axis indicates voltage.

As shown in FIG. 4, the optical sensor 1 according to the first embodiment samples the voltage of the digital signal SD and the voltages of the first to third delay signals SDL₁, SDL₂, and SDL₃ at the rising edge timings T1, T2, T3, T4, T5, and T6 of the clock signal SCLK within the measurement time. The voltage of the digital signal SD is the first voltage VH at the timings T1, T2, and T3, and is the second voltage VL at the timings T4, T5, and T6. Further, the voltages of the first and second delay signals SDL₁ and SDL₂ are the first voltage VH at the timings T2 and T3, and are the second voltage VL at the timings T1, T4, T5, and T6. Further, the voltage of the third SDL₃ is the first voltage VH at the timings T2, T3, and T4, and is the second voltage VL at the timings T1, T5, and T6. Thus, the count number is increased by one at the timing T1, is increased by four at each of the timings T2 and T3, is increased by one at the timing T4, and is maintained at each of the timings T5 and T6. Accordingly, a count number of 10 is obtained after the end of the measurement time.

The count number of 10 obtained by the optical sensor 1 according to the first embodiment is larger than the count number of 3 obtained by the optical sensor according to the reference example. This means that the sensitivity of the optical sensor 1 according to the first embodiment is higher than the sensitivity of the optical sensor according to the reference example. The count number of 10, which is obtained by the optical sensor 1 according to the first embodiment, does not quadruple the count number of 3, which is obtained by the optical sensor according to the reference example. This means that such a missing code that the count number obtained by the optical sensor 1 according to the first embodiment is limited to multiples of 4 does not occur, and that the quantization error of the optical sensor 1 according to the first embodiment does not increase. Such effects are obtained because the first to nth sampled voltages VS₁, VS₂, . . . , VSₙ₋₁, and VSₙ are equal to a sampled voltage of the digital signal SD sampled by the use of a clock signal having a frequency that is n-fold larger than the frequency of the clock signal SCLK. These effects are obtained without raising the sampling frequency and without elongating the measurement time.

The generator circuit 33 generates the clock signal SCLK. The delay amount Dis equal to 1/n of the period of the clock signal SCLK. This enables the sampled voltage VS and first to nth sampled voltages VS₁, VS₂, . . . , VSₙ₋₁, and VSₙ to be equal to a sampled voltage of the digital signal SD sampled by the use of a clock signal having a frequency that is n-fold larger than the frequency of the clock signal SCLK, and to be equal to a sampled voltage of the digital signal SD sampled at regular periods.

### 1.4 Sampling Circuit

As illustrated in FIG. 1, the sampling circuit 31 includes a flip-flop 41 and first to nth flip-flops 41₁, 41₂, . . . , 41ₙ₋₁, and 41ₙ. The flip-flop 41 includes an input terminal 41A, an output terminal 41B, and a clock terminal. 41C. The first to nth flip-flops 41₁, 41₂, . . . , 41ₙ₋₁, and 41ₙ respectively include input terminals 41A₁, 41A₂, . . . , 41Aₙ₋₁, and 41Aₙ, respectively include output terminals 41B₁, 41B₂, . . . , 41Bₙ₋₁, and 41Bₙ, and respectively include clock terminals 41C₁, 41C₂, . . . , 41Cₙ₋₁, and 41Cₙ.

The input terminal 41A of the flip-flop 41 is electrically connected to the input terminal 31A of the sampling circuit 31. The input terminals 41A₁, 41A₂, . . . , 41Aₙ₋₁, and 41Aₙ of the first to nth flip-flops 41₁, 41₂, . . . , 41ₙ₋₁, and 41ₙ are respectively electrically connected to the input terminals 31A₁, 31A₂, . . . , 31Aₙ₋₁, and 31Aₙ of the sampling circuit 31. The clock terminal 41C of the flip-flop 41 and the clock terminals 41C₁, 41C₂, . . . , 41Cₙ₋₁, and 41Cₙ of the first to nth flip-flops 41₁, 41₂, . . . , 41ₙ₋₁, and 41ₙ are connected to the clock terminal 31C of the sampling circuit 31. The output terminal 41B of the flip-flop 41 is electrically connected to the output terminal 31B of the sampling circuit 31. The output terminals 41B₁, 41B₂, . . . , 41Bₙ₋₁, and 41Bₙ of the first to nth flip-flops 41₁, 41₂, . . . , 41ₙ₋₁, and 41ₙ are respectively electrically connected to the output terminals 31B₁, 31B₂, . . . , 31Bₙ₋₁, and 31Bₙ of the sampling circuit 31.

The digital signal SD input to the input terminal 31A of the sampling circuit 31 is input to the input terminal 41A of the flip-flop 41. The first to nth delay signals SDL₁, SDL₂, . . . , SDLₙ₋₁, and SDLₙ input to the input terminals 31A₁, 31A₂, . . . , 31Aₙ₋₁, and 31Aₙ of the sampling circuit 31 are respectively input to the input terminals 41A₁, 41A₂, . . . , 41Aₙ₋₁, and 41Aₙ of the first to nth flip-flops 41₁, 41₂, . . . , 41ₙ₋₁, and 41ₙ. The clock signal SCLK input to the clock terminal 31C of the sampling circuit 31 is input to the clock terminal 41 of the flip-flop 41 and the clock terminals 41C₁, 41C₂, . . . , 41Cₙ₋₁, and 41Cₙ of the first to nth flip-flops 41₁, 41₂, . . . , 41ₙ₋₁, and 41ₙ. The flip-flop 41 samples the voltage of the input digital signal SD to output the sampled voltage VS, at the edge timing of the input clock signal SCLK. The first to nth flip-flops 41₁, 41₂, . . . , 41ₙ₋₁, and 41ₙ respectively sample the voltages of the input first to nth delay signals SDL₁, SDL₂, . . . , SDLₙ₋₁, and SDLₙ at the edge timing of the input clock signal SCLK, and respectively output the sampled voltages VS₁, VS₂, . . . , VSₙ₋₁, and VSₙ. The sampled voltage VS is output from the output terminal 41B of the flip-flop 41. The first to nth sampled voltages VS₁, VS₂, . . . , VSₙ₋₁, and VSₙ are respectively output from the output terminals 41B₁, 41B₂, . . . , 41Bₙ₋₁, and 41Bₙ of the first to nth flip-flops 41₁, 41₂, . . . , 41ₙ₋₁, and 41ₙ.

The flip-flop 41 and the first to nth flip-flops are each a D-type flip-flop or other kinds of flip-flop.

### 1.5 Operation Circuit

The operation circuit 32 includes a counter circuit 51, an accumulator circuit 52, and a resistor 53.

The counter circuit 51 is electrically connected to the output terminal 31B and output terminals 31B₁, 31B₂, . . . , 31Bₙ₋₁, and 31Bₙ of the sampling circuit 31.

The counter circuit 51 receives the sampled voltage VS output from the output terminal 31B of the sampling circuit 31, and the first to nth sampled voltages VS₁, VS₂, . . . , VSₙ₋₁, and VSₙ respectively output from the output terminals 31B₁, 31B₂, . . . , 31Bₙ₋₁, and 31Bₙ of the sampling circuit 31. The counter circuit 51 counts a total value TV of a value indicated by the sampled voltage VS, and first to nth values respectively indicated by the first to nth sampled voltages VS₁, VS₂, . . . , VSₙ₋₁, and VSₙ. The value indicated by the sampled voltage VS, and the values indicated by the respective first to nth sampled voltages VS₁, VS₂, . . . , VSₙ₋₁, and VSₙ stand at one when the individual voltages are the first voltage VH, and stand at zero when the individual voltages are the second voltage VL. This can count the number of voltages that are included in the sampled voltage VS and first to nth sampled voltages VS₁, VS₂, . . . , VSₙ₋₁, and VSₙ, and that are the first voltage VH.

The accumulator circuit 52 accumulates the total value TV over the measurement time to obtain the signal value SUM, and writes the obtained signal value SUM into the resistor 53. The resistor 53 undergone writing is read by another circuit.

### 1.6 ΔΣ Analog-to-Digital Converter

As illustrated in FIG. 1, the ΔΣ analog-to-digital converter 21 includes a subtractor 61, an integrator 62, a comparator 63, and a feedback circuit 64.

The subtractor 61 generates a residual signal SR by subtracting a subtraction signal composed of a current I2 from an analog signal composed of the current I1, by merging the current I2, which cancels out the current I1, into the current I1.

The integrator 62 integrates the generated residual signal SR to generate an integrated signal SI. The current I1 is a current for charging the integrator 62. The current I2 is a current for discharging the integrator 62.

The comparator 63 compares the voltage of the generated integrated signal SI and a reference voltage VREF with each other to generate the digital signal SD. The comparator 63 brings the voltage of the digital signal SD into the first voltage VH when the voltage of the integrated signal Si is higher than the reference voltage VREF, and brings the voltage of the digital signal SD into the second voltage VL when the voltage of the integrated signal SI is lower than the reference voltage VREF. The first voltage VH is higher than the second voltage VL and greater than 0 V for instance. The second voltage VL is 0 V for instance.

The feedback circuit 64 samples the voltage of the digital signal SD to generate the sampled voltage VS, and generates the current I2 in accordance with the generated voltage VS.

As illustrated in FIG. 1, the feedback circuit 64 includes the flip-flop 41, a pulse-width modulation (PWM) circuit 72, a reference current supply 73, and a switch 74.

The flip-flop 41 is shared by the sampling circuit 31 and the feedback circuit 64. The flip-flop 41 samples the voltage of the digital signal SD to output the sampled voltage VS.

The PWM circuit 72 subjects the generated voltage VS to PWM to generate a PWM-modulated voltage VPWM.

The reference current supply 73 generates a reference current.

When the PWM-modulated voltage VPWM is the first voltage VH, the switch 74 closes a line extending from the reference current supply 73 to the integrator 62, to reduce the residual signal SR with the current I2 as the reference signal. When the PWM-modulated voltage VPWM is the second voltage VL, the switch 74 opens the line extending from the reference current supply 73 to the integrator 62, to bring the current I2 into a current-free state and not to reduce the residual signal SR. The PWM circuit 72 may be omitted, and the sampled voltage VS may be used as it is instead of the PWM-modulated voltage VPWM.

As such, along with increase in the magnitude of the analog signal, the time during which the voltage of the digital signal SD is the first voltage VH elongates, the time during which the voltage of the digital signal SD is the second voltage VL shortens, and the pulse width of the digital signal SD widens.

The comparator 63 does not receive the clock signal SCLK. The comparator 63 thus compares the voltage of the integrated signal SI and the reference voltage VREF with each other to generate the digital signal SD, without synchronizing with the sampling circuit 31 sampling the voltage of the digital signal SD and the voltages of the first to nth delay signals SDL₁, SDL₂, . . . , SDLₙ₋₁, and SDLₙ. This can allow the voltage of the digital signal SD to rise from the second voltage VL to the first voltage VH at a timing that is off from the edge timing of the clock signal SCLK, and to fall from the first voltage VH to the second voltage VL at a timing that is off from the edge timing of the clock signal SCLK, thereby preventing increase in quantization error.

While there have been described what are at present considered to be certain embodiments of the invention, it will be understood that various modifications may be made thereto, and it is intended that the appended claim cover all such modifications as fall within the true spirit and scope of the invention.

What is claimed is:

1. An analog-to-digital conversion device comprising:
a ΔΣ analog-to-digital converter configured to convert an analog signal into a digital signal having a pulse width corresponding to a magnitude of the analog signal;
first to nth delay circuits, the first delay circuit being configured to delay the digital signal to generate a first delay signal, the ith delay circuit being configured to delay an i−1th delay signal to generate an ith delay signal, where i is an integer equal to or greater than two and equal to or smaller than n, and where n is an integer equal to or greater than two; and
a signal processing circuit configured to obtain a signal value corresponding to the magnitude, from the digital signal and the first delay signal to an nth delay signal.

2. The analog-to-digital conversion device according to claim 1, wherein
the signal processing circuit includes
a sampling circuit configured to sample a voltage of the digital signal to output a sampled voltage, and configured to sample voltages of the first to nth delay signals to individually output first to nth sampled voltages, and
an operation circuit configured to obtain the signal value from the sampled voltage and the first to nth sampled voltages.

3. The analog-to-digital conversion device according to claim 2, wherein
the sampling circuit includes
a flip-flop configured to receive the digital signal and output the sampled voltage, and
first to nth flip-flops configured to respectively receive the first to nth delay signals and respectively output the first to nth sampled voltages.

4. The analog-to-digital conversion device according to claim 2, wherein
the signal processing circuit includes a generator circuit configured to generate a clock signal, and
the sampling circuit samples the voltage of the digital signal and the voltages of the first to nth delay signals in synchronization at an edge timing of the clock signal.

5. The analog-to-digital conversion device according to claim 4, wherein
the first delay circuit delays the digital signal by a delay amount equal to 1/n of a period of the clock signal, and
the ith delay circuit delays the i−1th delay signal by the delay amount.

6. The analog-to-digital conversion device according to claim 2, wherein
the operation circuit includes
a counter circuit configured to count a total value of a value indicated by the sampled voltage, and first to nth values respectively indicated by the first to nth sampled voltages, and
an accumulator circuit configured to accumulate the total value over a measurement time to obtain the signal value.

7. The analog-to-digital conversion device according to claim 1, wherein
the ΔΣ analog-to-digital converter includes
a subtracter configured to subtract a subtraction signal from the analog signal to generate a residual signal,
an integrator configured to integrate the residual signal to generate an integrated signal,
a comparator configured to compare a voltage of the integrated signal and a reference voltage with each other to generate the digital signal, and
a feedback circuit configured to sample a voltage of the digital signal to generate a sampled voltage, and configured to generate the subtraction signal in accordance with the sampled voltage.

8. The analog-to-digital conversion device according to claim 7, wherein
the signal processing circuit includes a sampling circuit configured to sample a voltage of the digital signal to generate a sampled voltage, and configured to sample voltages of the first to nth delay signals to generate first to nth sampled voltages, and
the comparator compares the voltage of the integrated signal and the reference voltage with each other to generate the digital signal, without synchronizing with the sampling circuit sampling the voltage of the digital signal and the voltages of the first to nth delay signals.

9. An optical sensor comprising:
the analog-to-digital conversion device according to claim 1; and
a light detecting element configured to convert light into the analog signal.
